(19) United States
(12) Patent Application Publication
(10) Pub. No.: US 2023/0170437 A1
(43) Pub. Date: Jun. 1, 2023

(54) SEMICONDUCTOR EPITAXIAL STRUCTURE AND METHOD FOR MANUFACTURING THE SAME, AND LED

(71) Applicant: Chongqing Konka Photoelectric Technology Research Institute Co., Ltd., Chongqing (CN)

(72) Inventor: Weiwei SUN, Chongqing (CN)

(21) Appl. No.: 18/152,902

(22) Filed: Jan. 11, 2023

Related U.S. Application Data
(63) Continuation of application No. PCT/CN2021/129776, filed on Nov. 10, 2021.

(51) Int. Cl. H01L 33/06; H01L 33/30; H01L 33/00

(52) U.S. Cl. CPC H01L 33/06; H01L 33/0062; H01L 33/305

(57) ABSTRACT

A semiconductor epitaxial structure and a method for manufacturing the same, and a light-emitting diode are provided. The semiconductor epitaxial structure includes a first-type semiconductor layer, a light-emitting layer, and a second-type semiconductor layer. The light-emitting layer is disposed on the first-type semiconductor layer. The second-type semiconductor layer is disposed on the light-emitting layer. The light-emitting layer includes potential well layers and potential barrier layers which are repeatedly stacked. At least part of potential barrier layers belonging to intermediate layers of the light-emitting layer is doped, and has a doping type same as the second-type semiconductor layer.

### CROSS-REFERENCE TO RELATED APPLICATION(S)

This application is a continuation of International Application No. PCT/CN2021/129776, filed Nov. 10, 2021, the disclosure of which is hereby incorporated by reference in its entirety.

### TECHNICAL FIELD

This application relates to the field of semiconductor manufacturing technology, and particularly to a semiconductor epitaxial structure and a method for manufacturing the same, and a light-emitting diode (LED).

### BACKGROUND

Quaternary materials such as aluminum gallium indium phosphide (AlGaInP) has been widely used in preparation of various optoelectronic devices. The quaternary material is used to prepare high-brightness light-emitting diodes (LED), and a light-emitting band of these LEDs can cover red to blue-green band of visible light. Therefore, these LEDs have been widely used in many aspects such as outdoor displays, traffic lights, and car lights. Plant lights made of quaternary material AlGaInP have a huge market, which can reduce cultivation costs and achieve anti-season cultivation. However, an LED used in plant lighting is required to have a high light efficiency and a stable light output power during cultivation.

Therefore, how to further improve reliability of an LED is an urgent problem to-be-solved.

### SUMMARY

The disclosure provides a semiconductor epitaxial structure. The semiconductor epitaxial structure includes a first-type semiconductor layer, a light-emitting layer, and a second-type semiconductor layer. The light-emitting layer is disposed on the first-type semiconductor layer. The second-type semiconductor layer is disposed on the light-emitting layer. The light-emitting layer includes potential well layers and potential barrier layers that are repeatedly stacked. At least part of potential barrier layers belonging to intermediate layers of the light-emitting layer is doped, and has a doping type same as the second-type semiconductor layer.

The disclosure further provides a method for manufacturing a semiconductor epitaxial structure. The method includes the following. A substrate is provided. A first-type semiconductor layer is formed on the substrate. A light-emitting layer is formed on the first-type semiconductor layer. A second-type semiconductor layer is formed on the light-emitting layer. The light-emitting layer includes potential well layers and potential barrier layers that are repeatedly stacked. At least part of potential barrier layers belonging to intermediate layers of the light-emitting layer is doped, and has a doping type same as the second-type semiconductor layer.

The disclosure further provides a light-emitting diode (LED). The LED includes a semiconductor epitaxial structure, a first electrode, and a second electrode. The semiconductor epitaxial structure includes a first-type semiconductor layer, a light-emitting layer, and a second-type semiconductor layer. The light-emitting layer is disposed on the first-type semiconductor layer. The second-type semiconductor layer is disposed on the light-emitting layer. The light-emitting layer includes potential well layers and potential barrier layers that are repeatedly stacked. At least part of potential barrier layers belonging to intermediate layers of the light-emitting layer is doped, and has a doping type same as the second-type semiconductor layer. The first electrode is coupled with the first-type semiconductor layer. The second electrode is coupled with the second-type semiconductor layer.

### BRIEF DESCRIPTION OF THE DRAWINGS

In order to describe technical solutions of implementations of the disclosure more clearly, the following will give a brief description of accompanying drawings used for describing the implementations. Apparently, accompanying drawings described below are merely some implementations. Those of ordinary skill in the art can also obtain other accompanying drawings based on the accompanying drawings described below without creative efforts.

FIG. 1 is a schematic diagram illustrating a semiconductor epitaxial structure of the disclosure.

FIG. 2 is a schematic structural diagram illustrating a light-emitting layer in FIG. 1 of the disclosure.

FIG. 3 is a schematic structural diagram illustrating a first-type semiconductor layer in FIG. 1 of the disclosure.

FIG. 4 is a schematic structural diagram illustrating a second-type semiconductor layer in FIG. 1 of the disclosure.

FIG. 5 is a schematic structural diagram illustrating a light-emitting diode (LED) of the disclosure.

FIG. 6 is a schematic structural diagram illustrating a lamp board of an electronic device of the disclosure.

Explanation of reference signs:

10-substrate; 11-first-type semiconductor layer; 111-buffer layer; 112-etching stop layer; 113-ohmic contact layer; 114-current spreading layer; 115-first confinement layer; 116-first waveguide layer; 12-light-emitting layer; 121-first potential well layer; 122-first potential barrier layer; 1221-first potential barrier sub-layer; 1222-second potential barrier sub-layer; 1223-third potential barrier sub-layer; 123-second potential well layer; 124-second potential barrier layer; 1241-potential barrier sub-layer; 1242-second potential barrier sub-layer; 1243-third potential barrier sub-layer; 125-third potential well layer; 126-third potential barrier layer; 1261-first potential barrier sub-layer; 1262-second potential barrier sub-layer; 1263-third potential barrier sub-layer; 13-second-type semiconductor layer; 131-second waveguide layer; 132-second confinement layer; 133-transition layer; 134-window layer; 14-first electrode; 15-second electrode; 16-passivation layer; 2-plant lights; 20-lamp board.

### DETAILED DESCRIPTION

In order to facilitate understanding of the disclosure, the disclosure will be described fully below with reference to accompanying drawings. The accompanying drawings illustrate exemplary implementations of the disclosure. However, the disclosure may be implemented in many different forms and is not limited to the implementations described herein. Rather, these implementations are provided to achieve a thorough and complete understanding of disclosed contents of the disclosure.

Unless otherwise defined, all technical and scientific terms herein have the same meaning as commonly understood by one of ordinary skill in the technical field to which the disclosure belongs. The terms herein are merely for the purpose of describing implementations of the disclosure, which are not intended to limit the disclosure.

In description of the disclosure, it should be noted that, orientations or positional relationships indicated by the terms “center”, “upper”, “lower”, “left”, “right”, and the like are based on orientations or positional relationships illustrated in the accompanying drawings, and are only for convenience of describing the disclosure and simplifying the description, rather than indicating or implying that the referred device or element must have a specific orientation, be constructed and operated in a specific orientation, and therefore should not be construed as a limitation of the disclosure. In addition, the terms “first”, “second”, and the like are used for descriptive only and should not be construed to indicate or imply relative importance.

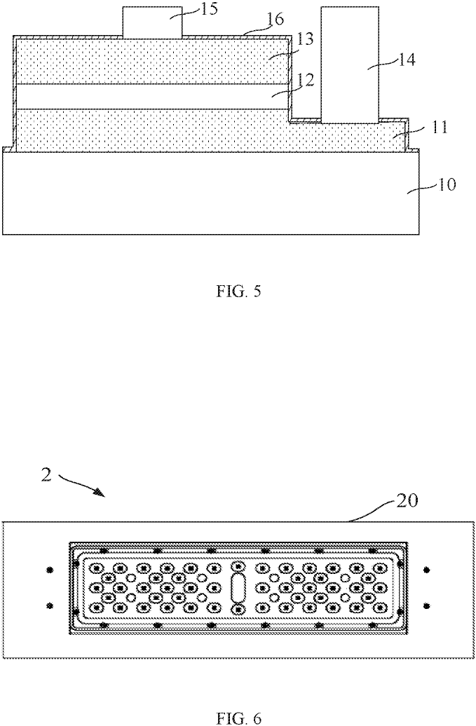

Aluminum gallium indium phosphide (AlGaInP) multiple quantum wells can emit light having a wide range of a wavelength band, and can be widely used in electronic devices, for example, used as a light-emitting layer in a light-emitting diode (LED) and a laser diode. The laser diode made of AlGaInP can be used in lasers, and the LED made of AlGaInP can be used in various display devices and various electronic devices, such as displays, billboards, lights, and display lights. In addition, referring to FIG. 6, since the LED made of AlGaInP can emit light having a wide range of a wavelength band, the LED made of AlGaInP can also be used in a plant light 2, to realize anti-season cultivation of plants. Specifically, the plant light 2 includes a lamp board 20 and a control apparatus (not illustrated). The lamp board 20 is provided with multiple LEDs. The control apparatus can be fixed on the lamp board 20, or the control apparatus can be lead-out through a wire and arranged at a place where easy to operate. A state of the LED can be adjusted by adjusting the control apparatus, including controlling on/off and a light intensity of the LED. In order to ensure a growth quality of plants, the disclosure provides a semiconductor epitaxial structure and an LDE with a high light efficiency and a stable light output power, so that the LDE and an electronic device have a higher light efficiency.

In view of the above deficiencies of the related art, the disclosure provides a semiconductor epitaxial structure and a method for manufacturing the same, and a light-emitting diode (LED), which aims to solve a problem of how to further improve reliability of the LED.

In order to solve the above technical problem, the disclosure is achieved through the following technical solutions.

The disclosure provides a semiconductor epitaxial structure. The semiconductor epitaxial structure includes a first-type semiconductor layer, a light-emitting layer, and a second-type semiconductor layer. The light-emitting layer is disposed on the first-type semiconductor layer. The second-type semiconductor layer is disposed on the light-emitting layer. The light-emitting layer includes potential well layers and potential barrier layers that are repeatedly stacked. At least part of potential barrier layers belonging to intermediate layers of the light-emitting layer is doped, and has a doping type same as the second-type semiconductor layer.

In the semiconductor epitaxial structure, the potential barrier layer having the same doping type as the second-type semiconductor layer is provided in the intermediate region of the light-emitting layer, which can provide a higher hole concentration and reduce a series resistance, so that the device has a better thermal effect than a conventional structure, and moreover, lower junction heat can make carriers in a quantum well easier to be trapped, thereby increasing a luminous efficiency. In addition, higher hole concentration can improve a recombination efficiency, thereby increasing a light output efficiency.

Optionally, a total number of repetitions of the potential well layer and the potential barrier layer ranges from 12 to 20.

Optionally, a number of repetitions of a potential barrier layer doped and a corresponding potential well layer ranges from 4 to 6.

Nearly one-third of potential barrier layers in the intermediate region has dopant ions, which can avoid degrading of crystal quality and electrical abnormalities of the semiconductor epitaxial structure and the LED caused by introduction of impurities due to excessive ion doping in the light-emitting layer, while ensuring that the light-emitting layer has a higher doping concentration.

Optionally, the potential barrier layer includes a first potential barrier sub-layer, a second potential barrier sub-layer, and a third potential barrier sub-layer. The first potential barrier sub-layer, the second potential barrier sub-layer, and the third potential barrier sub-layer are sequentially stacked.

Optionally, the first potential barrier sub-layer in the potential barrier layer doped is doped; and/or the second potential barrier sub-layer in the potential barrier layer doped is doped; and/or the third potential barrier sub-layer in the potential barrier layer doped is doped.

Optionally, the potential barrier layer doped is P-type doped, and a dopant source of the potential barrier layer doped is diethylzinc.

The above diethylzinc has a diffusion effect, and zinc in the potential barrier sub-layer in the intermediate region will diffuse to both sides to increase a hole concentration in the light-emitting layer and reduce a series resistance.

Optionally, the first-type semiconductor layer includes an etching stop layer and an ohmic contact layer. The ohmic contact layer is formed on the etching stop layer.

The etching stop layer can prevent a substrate from being etched when forming the LED, and the ohmic contact layer can form a good ohmic contact with an electrode.

Optionally, the first-type semiconductor layer further includes a current spreading layer, a first confinement layer, and a first waveguide layer. The current spreading layer is formed on the ohmic contact layer. The first confinement layer is formed on the current spreading layer. The first waveguide layer is formed on the first confinement layer.

The current spreading layer can enhance a current spreading capability, the first confinement layer can provide electrons for the light-emitting layer while preventing carriers from overflowing the light-emitting layer, and the first waveguide layer can prevent impurities from diffusing into the light-emitting layer.

Optionally, the second-type semiconductor layer includes a second waveguide layer, a second confinement layer, a transition layer, and a window layer. The second waveguide layer is disposed on the light-emitting layer. The second confinement layer is disposed on the second waveguide layer. The transition layer is disposed on the second confinement layer. The window layer is disposed on the transition layer.

The second waveguide layer can prevent impurities from diffusing into a light-emitting layer, the second confinement layer can provide holes for the light-emitting layer while preventing carriers from overflowing the light-emitting layer, the waveguide layer is conducive to growth of a GaP crystal, and the window layer can enhance a current spreading capability and form a good ohmic contact with an electrode.

Based on the same inventive concept, the disclosure further provides a method for manufacturing a semiconductor epitaxial structure. The method includes the following. A substrate is provided. A first-type semiconductor layer is formed on the substrate. A light-emitting layer is formed on the first-type semiconductor layer. A second-type semiconductor layer is formed on the light-emitting layer. The light-emitting layer includes potential well layers and potential barrier layers that are repeatedly stacked. At least part of potential barrier layers belonging to intermediate layers of the light-emitting layer is doped, and has a doping type same as the second-type semiconductor layer.

A semiconductor epitaxial structure with a high light efficiency can be formed through the above method for manufacturing the semiconductor epitaxial structure.

Optionally, the potential well layer is formed as follows. Under a preset temperature and chamber pressure, phosphine is inlet, with hydrogen as a carrier gas, and a preset proportion of trimethylgallium or a preset proportion of trimethylindium is inlet. A first deposition time is controlled and the potential well layer with a first thickness is grown.

Optionally, the potential barrier layer includes a first potential barrier sub-layer, a second potential barrier sub-layer, and a third potential barrier sub-layer. A potential barrier layer doped is formed as follows. After forming the potential well layers, trimethylaluminum is inlet into a reaction chamber, a proportion of the trimethylgallium, a proportion of the trimethylaluminum, and a proportion of the trimethylindium are adjusted, a second deposition time is controlled, and a first potential barrier sub-layer with a second thickness is grown. A growing condition for forming the first potential barrier sub-layer is maintained, diethylzinc is inlet into the reaction chamber, the second deposition time is controlled, and a second potential barrier sub-layer with a third thickness is grown. A growing condition for forming the second potential barrier sub-layer is maintained, stop inletting of the diethylzinc into the reaction chamber, the second deposition time is controlled, and a third potential barrier sub-layer with a fourth thickness is grown.

Optionally, a doping concentration of zinc ions in the second potential barrier sub-layer ranges from 6×10¹⁷ atoms/cm² to 1×10¹⁸ atoms/cm².

The zinc ions have such a doping concentration, which can ensure that the light-emitting layer has a higher doping concentration, and avoid degrading of crystal quality and electrical abnormalities of the semiconductor epitaxial structure and the LED caused by introduction of impurities due to excessive ion doping in the light-emitting layer.

Based on the same inventive concept, the disclosure further provides an LED. The LED includes a semiconductor epitaxial structure, a first electrode, and a second electrode. The semiconductor epitaxial structure includes a first-type semiconductor layer, a light-emitting layer, and a second-type semiconductor layer. The light-emitting layer is disposed on the first-type semiconductor layer. The second-type semiconductor layer is disposed on the light-emitting layer. The light-emitting layer includes potential well layers and potential barrier layers that are repeatedly stacked. At least part of potential barrier layers belonging to intermediate layers of the light-emitting layer is doped, and has a doping type same as the second-type semiconductor layer. The first electrode is coupled with the first-type semiconductor layer. The second electrode is coupled with the second-type semiconductor layer.

The LED can be realized as an LED with a high light efficiency and a stable light output power through setting of the light-emitting layer.

Based on the same inventive concept, the disclosure further provides an electronic device. The electronic device includes a control apparatus and a lamp board. The lamp board is electrically coupled with the control apparatus and provided with a plurality of LEDs. The LED includes a semiconductor epitaxial structure, a first electrode, and a second electrode. The semiconductor epitaxial structure includes a first-type semiconductor layer, a light-emitting layer, and a second-type semiconductor layer. The light-emitting layer is disposed on the first-type semiconductor layer. The second-type semiconductor layer is disposed on the light-emitting layer. The light-emitting layer includes potential well layers and potential barrier layers that are repeatedly stacked. At least part of potential barrier layers belonging to intermediate layers of the light-emitting layer is doped, and has a doping type same as the second-type semiconductor layer. The first electrode is coupled with the first-type semiconductor layer. The second electrode is coupled with the second-type semiconductor layer.

The electronic device has a high light efficiency and a stable light output power through setting of the LED.

Any product of implementations of the disclosure does not necessarily need to achieve all the above-mentioned advantages at the same time.

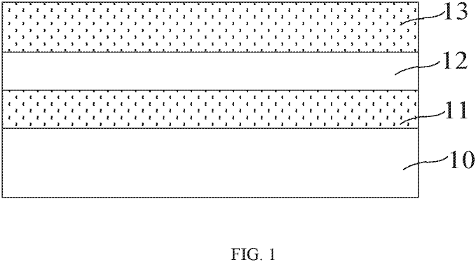

Referring to FIG. 1, a semiconductor epitaxial structure of the disclosure includes a first-type semiconductor layer 11, a light-emitting layer 12, and a second-type semiconductor layer 13. The first-type semiconductor layer 11 is disposed on a substrate 10. The light-emitting layer 12 is disposed on the first-type semiconductor layer 11. The second-type semiconductor layer 13 is disposed on the light-emitting layer 12. By applying a voltage to the first-type semiconductor layer 11 and the second-type semiconductor layer 13, photons and holes are recombined, and then energy is emitted in the form of photons, so that the semiconductor epitaxial structure emits light.

Referring to FIG. 1, in an implementation of the disclosure, the LED is, for example, a red LED, and the substrate 10 is, for example, a substrate made of a gallium arsenide (GaAs). In this implementation, the substrate 10 is, for example, doped with silicon ions. In other implementations, when the LED is a blue LED or a green LED, the substrate 10 may also be a substrate made of silicon (Si), silicon carbide (SiC), sapphire (Al₂O₃), etc. As an example, a blue LED or a green LED can be directly grown on and directly formed on a sapphire substrate.

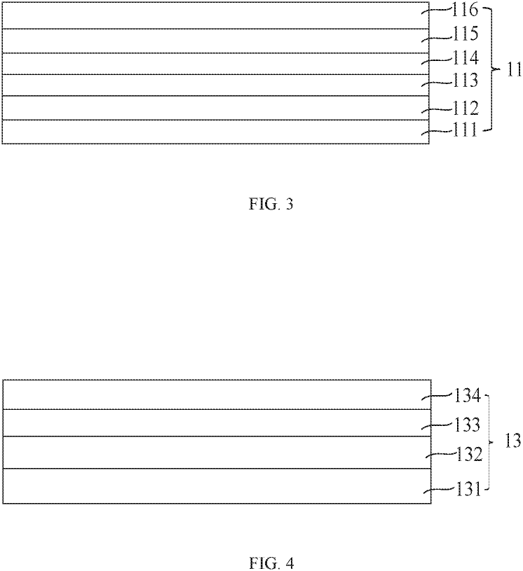

Referring to FIG. 1 and FIG. 3, in an implementation of the disclosure, the first-type semiconductor layer 11 is formed on the substrate 10, and the first-type semiconductor layer 11 may be an N-type semiconductor layer with more electrons or a P-type semiconductor layer with more holes. In this implementation, the first-type semiconductor layer 11 is, for example, an N-type semiconductor layer, and the first-type semiconductor layer 11 is doped with donor impurities, such as silicon (Si) or tellurium (Te). The first-type semiconductor layer 11 includes a buffer layer 111, an etching stop layer 112, an ohmic contact layer 113, a current spreading layer 114, a first confinement layer 115, and a first waveguide layer 116 which are disposed on the substrate 10 in sequence.

Specifically, referring to FIG. 1 and FIG. 3, in an implementation of the disclosure, the buffer layer 111 is disposed on the substrate 10, and the buffer layer 111 is, for example, made of N-type gallium arsenide (GaAs). In this implementation, a thickness of the buffer layer 111 is, for example, in a range of 10 nm to 20 nm, such as 12 nm, 15 nm, or 18 nm. As an example, the buffer layer 111 is doped with silicon ions, and has an ion doping concentration of 1 × 10¹⁸ atoms/cm² to 2× 10¹⁸ atoms/cm². The buffer layer 111 can reduce lattice mismatch between the substrate 10 and other first-type semiconductor layers 11 on the buffer layer 111. The etching stop layer 112 is disposed on the buffer layer 111, and the etching stop layer 112 is, for example, made of N-type gallium indium phosphide (Gaₓ₁In₁₋ₓ₁P), where X1 is, for example, 0.5, that is, the etching stop layer 112 is made of Ga_{0.5}In_{0.5}P. In this implementation, a thickness of the etching stop layer 112 is, for example, in a range of 20 nm to 50 nm, such as 30 nm, 35 nm, or 40 nm. As an example, the etching stop layer 112 is doped with silicon ions, and has an ion doping concentration of 1 ×10¹⁸ atoms/cm² to 2× 10¹⁸ atoms/cm². The etching stop layer 112 can prevent the substrate 10 and the buffer layer 111 from being corroded when etching epitaxy to form an LED. The ohmic contact layer 113 is disposed on the etching stop layer 112, and the ohmic contact layer 113 is, for example, made of N-type gallium arsenide (GaAs). In this implementation, a thickness of the ohmic contact layer 113 is, for example, in a range of 10 nm to 30 nm, such as 15 nm, 20 nm, or 25 nm. As an example, the ohmic contact layer 113 is doped with silicon ions, and has an ion doping concentration of 2 ×10¹⁸ atoms/cm² to 3 ×10¹⁸ atoms/cm². When the LED is formed, one of electrodes is in contact with the ohmic contact layer 113. A doping concentration of ions in the ohmic contact layer 113 is relatively high, which can enhance an electrical connection between the ohmic contact layer 113 and the electrode. The current spreading layer 114 is disposed on the ohmic contact layer 113 to increase a current spreading capability of the N-type semiconductor layer. The current spreading layer 114 is, for example, made of N-type aluminum gallium indium phosphide (Alₓ₂Ga₁₋ₓ₂InP), where X2 is in a range of 0.3 to 0.6, such as 0.4, 0.5, or 0.55. In this implementation, a thickness of the current spreading layer 114 is, for example, in a range of 10 nm to 30 nm, such as 15 nm, 20 nm, or 25 nm. As an example, the current spreading layer 114 is doped with silicon ions, and has an ion doping concentration of 1 ×10¹⁸ atoms/cm² to 2 ×10¹⁸ atoms/cm².

Referring to FIG. 3, in an implementation of the disclosure, the first confinement layer 115 is disposed on the current spreading layer 114, and the first confinement layer 115 is, for example, made of N-type aluminum indium phosphide (Alₓ₃In₁₋ₓ₃P), where X3 is, for example, 0.5, that is, the first confinement layer 115 is made of Al_{0.5}In_{0.5}P. In this implementation, a thickness of the first confinement layer 115 is, for example, in a range of 30 nm to 80 nm, such as 50 nm, 60 nm, or 70 nm. As an example, the first confinement layer 115 is doped with silicon ions, and has an ion doping concentration of 7 ×10¹⁷ atoms/cm² to 1 × 10¹⁸ atoms/cm², which can provide electrons for the light-emitting layer and prevent carriers from overflowing the light-emitting layer. The first waveguide layer 116 is disposed on the first confinement layer 115, and the first waveguide layer 116 is, for example, made of N-type aluminum gallium indium phosphide (Alₓ₄Ga₁₋ₓ₄InP), where X4 is, for example, in a range of 0.5 to 0.7, such as 0.55, 0.6, or 0.65. In this implementation, a thickness of the first waveguide layer 116 is, for example, in a range of 30 nm to 60 nm, such as 30 nm, 40 nm, 50 nm, or 60 nm. The first waveguide layer 116 of the disclosure is not doped with other ions, which can prevent impurities between the first waveguide layer 116 and the substrate 10 from diffusing into the light-emitting layer.

Referring to FIG. 1 and FIG. 3, in an implementation of the disclosure, the buffer layer 111, the etching stop layer 112, and the ohmic contact layer 113, the current spreading layer 114, the first confinement layer 115, and the first waveguide layer 116 are sequentially deposited on the substrate 10 through metal-organic chemical vapour deposition (MOCVD).

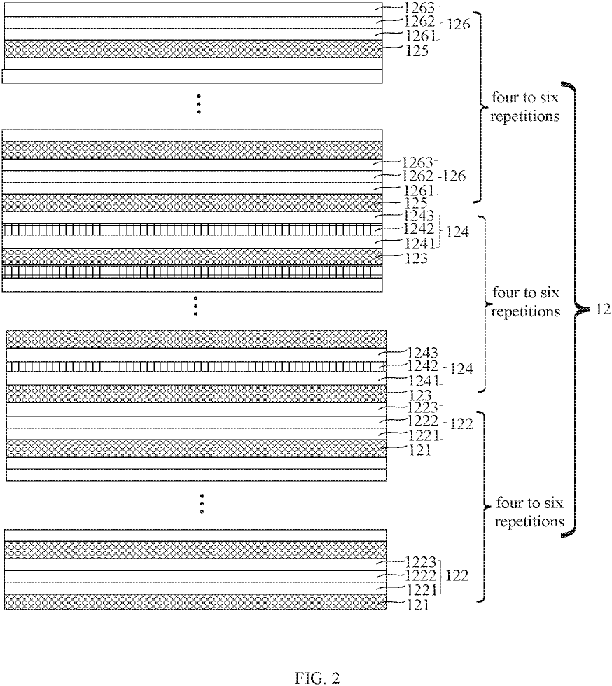

Referring to FIG. 1 and FIG. 2, in an implementation of the disclosure, the light-emitting layer 12 is disposed on the first-type semiconductor layer 11, and the light-emitting layer 12 may be a quantum well light-emitting layer, or may be an intrinsic semiconductor layer or a low doped semiconductor layer. In this implementation, the light-emitting layer 12 is, for example, a quantum well light-emitting layer, and includes multiple repeatedly stacked gallium indium phosphide layers/aluminum gallium indium phosphide layers (Gaₓ₁₁In₁₋ₓ₁₁P/Alₓ₁₂Ga₁₋ ₓ₁₂)_{0.5}In_{0.5}P). In other implementations, the light-emitting layer 12 can also be made of one or more of indium gallium nitride (InGaN), zinc selenide (ZnSe), indium gallium nitride/gallium nitride (InGaN/GaN), gallium phosphide (GaP), aluminum gallium phosphide (AlGaP), aluminum gallium arsenide (AlGaAs), gallium phosphide (GaP), etc.

Referring to FIG. 2, in an implementation of the disclosure, the light-emitting layer 12 includes multiple potential well layers and multiple potential barrier layers that are repeatedly (or periodically) stacked, and the total number of repetitions (or periods) of the potential well layer and the potential barrier layer, for example, ranges from 12 to 20. The potential well layer is, for example, made of gallium indium phosphide, and the potential barrier layer is, for example, made of aluminum gallium indium phosphide. In the disclosure, the potential well layer is an undoped layer, part of the potential barrier layers is an undoped layer, and part of the potential barrier layers is a doped layer having a same doping type as the second-type semiconductor layer 13. The doped potential barrier layer can be located in any region of the light-emitting layer 12. In this implementation, in order to ensure uniform diffusion of ions in the light-emitting layer, the doped potential barrier layer is located in an intermediate region of the light-emitting layer 12. It should be noted that, the “any region” herein refers to any layer of the light-emitting layer 12 (including stacked layers), and the “intermediate region” herein refers to an intermediate layer(s) of the light-emitting layer 12 rather than the top layer or the bottom layer of the light-emitting layer 12. As an example, multiple potential barrier layers in multiple repetitions close to the first-type semiconductor layer 11 and the second-type semiconductor layer 13 are undoped layers. For each of multiple potential barrier layers in multiple repetitions corresponding to the intermediate region of the light-emitting layer 12, one or more potential barrier sub-layers (e.g., a P-type potential barrier sub-layer) having a same doping type as the second-type semiconductor layer are provided. In this implementation, the number of repetitions of the doped potential barrier layer is close to one-third of the total number of repetitions, which can avoid degrading of crystal quality and electrical abnormalities of the semiconductor epitaxial structure and the LED caused by introduction of impurities due to excessive ion doping in the light-emitting layer, while ensuring that the light-emitting layer has a higher doping concentration.

Specifically, referring to FIG. 2, in this implementation, the light-emitting layer 12 includes multiple first potential well layers 121 and multiple first potential barrier layers 122 that are repeatedly stacked, multiple second potential well layers 123 and multiple second potential barrier layers 124 that are repeatedly stacked, and multiple third potential well layers 125 and multiple third potential barrier layers 126 that are stacked repeatedly. In this implementation, the multiple first potential well layers 121 and the multiple first potential barrier layers 122 repeatedly stacked are disposed on the first-type semiconductor layer 11, the multiple second potential well layers 123 and the multiple second potential barrier layers 124 repeatedly stacked are disposed on the multiple first potential well layers 121 and the multiple first potential barrier layers 122 repeatedly stacked, and the multiple third potential well layers 125 and the multiple third potential barrier layers 126 repeatedly stacked are disposed on the multiple second potential well layers 123 and the multiple second potential barrier layers 124 repeatedly stacked. The potential well layer and the potential barrier layer are alternatively disposed. In other implementations, the multiple second potential well layers 123 and the multiple second potential barrier layers 124 repeatedly stacked may be disposed on one side of the multiple first potential well layers 121 and the multiple first potential barrier layers 122 repeatedly stacked, where the side is close to the first-type semiconductor layer 11. The first number of repetitions of the first potential well layer 121 and the first potential barrier layer 122 is, for example, in a range of 4 to 6, the second number of repetitions of the second potential well layer 123 and the second potential barrier layer 124 is, for example, in a range of 4 to 6, and the third number of repetitions of the third potential well layer 125 and the third potential barrier layer 126 is, for example, in a range of 4 to 6. The first number, the second number, and the third number may the same or different. In this implementation, the light-emitting layer 12 includes, for example, five repetitions of the first potential well layer 121 and the first potential barrier layer 122, five repetitions of the second potential well layer 123 and the second potential barrier layer 124, and five repetitions of the third potential well layer 125 and the third potential barrier layer 126. In other implementations, the light-emitting layer 12 includes, for example, six repetitions of the first potential well layer 121 and the first potential barrier layer 122, five repetitions of the second potential well layer 123 and the second potential barrier layer 124, and six repetitions of the third potential well layer 125 and the third potential barrier layer 126. In other implementations, the light-emitting layer 12 includes, for example, five repetitions of the first potential well layer 121 and the first potential barrier layer 122, six repetitions of the second potential well layer 123 and the second potential barrier layer 124, and five repetitions of the third potential well layer 125 and the third potential barrier layer 126.

Referring to FIG. 2, in an implementation of the disclosure, the material of the first potential well layer 121, the material of the second potential well layer 123, and the material of the third potential well layer 125 are the same, such as gallium indium phosphide (Gaₓ₁₁In₁₋ ₓ₁₁P), where X11 is in a range of 0.45 to 0.5, such as 0.46, 0.47, 0.48, or 0.49. A thickness of the first potential well layer 121, a thickness of the second potential well layer 123, and a thickness of the third potential well layer 125 each are in a range of 8 nm to 10 nm. The thickness of the first potential well layer 121, the thickness of the second potential well layer 123, and the thickness of the third potential well layer 125 may be the same or different. In this implementation, the thicknesses of the first potential well layer 121, the thicknesses of the second potential well layer 123, and the thicknesses of the third potential well layer 125 each are, for example, 9 nm. In another implementation, the thickness of the first potential well layer 121 and the thickness of the third potential well layer 125 each are, for example, 9 nm, and the thickness of the second potential well layer 123 is, for example, 10 nm. In this implementation, the first potential well layer 121, the second potential well layer 123, and the third potential well layer 125 each are undoped layers.

Referring to FIG. 2, in an implementation of the disclosure, the material of the first potential barrier layer 122, the material of the second potential barrier layer 124, and the material of the third potential barrier layer 126 are the same, such as (Alₓ₁₂Ga₁₋ₓ₁₂)_{0.5}In_{0.5}P, where X12 is in a range of 0.5 to 0.7, for example, 0.55, 0.6, or 0.65. The thickness of the first potential barrier layer 122, the thickness of the second potential barrier layer 124, and the thickness of the third potential barrier layer 126 each are in a range of 18 nm to 24 nm. The thickness of the first potential barrier layer 122, the thickness of the second potential barrier layer 124, and the thickness of the third potential barrier layer 126 may be the same or different. In this implementation, the thicknesses of the first potential barrier layer 122, the thicknesses of the second potential barrier layer 124, and the thicknesses of the third potential barrier layer 126 each are, for example, 21 nm.

Specifically, referring to FIG. 2, in this implementation, the first potential barrier layer 122, the second potential barrier layer 124, and the third potential barrier layer 126 each include three sub-layers. The first potential barrier layer 122 includes, for example, a first potential barrier sub-layer 1221, a second potential barrier sub-layer 1222, and a third potential barrier sub-layer 1223. The second potential barrier sub-layer 1222 is disposed on the first potential barrier sub-layer 1221, and the third potential barrier sub-layer 1223 is disposed on the second potential barrier sub-layer 1222. The second potential barrier layer 124 includes, for example, a first potential barrier sub-layer 1241, a second potential barrier sub-layer 1242, and a third potential barrier sub-layer 1243. The second potential barrier sub-layer 1242 is disposed on the first potential barrier sub-layer 1241, and the third potential barrier sub-layer 1243 is disposed on the second potential barrier sub-layer 1242. The third potential barrier layer 126 includes, for example, a first potential barrier sub-layer 1261, a second potential barrier sub-layer 1262, and a third potential barrier sub-layer 1263. The second potential barrier sub-layer 1262 is disposed on the first potential barrier sub-layer 1261, and the third potential barrier sub-layer 1263 is disposed on the second potential barrier sub-layer 1262. Each potential barrier sub-layer has a same thickness, for example, a thickness of 6 nm to 8 nm, such as 7 nm. In the first potential barrier layer 122, the first potential barrier sub-layer 1221, the second potential barrier sub-layer 1222, and the third potential barrier sub-layer 1223 each are not doped with ions. In the third potential barrier layer 126, the first potential barrier sub-layer 1261, the second potential barrier sub-layer 1262, and the third potential barrier sub-layer 1263 each are not doped with ions. In other implementations, the first potential barrier sub-layer 1221/1261, the second potential barrier sub-layer 1222/1262, and the third potential barrier sub-layer 1223/1263 each are doped with same ions (or have a same doping type) as the second-type semiconductor layer 13. Referring to FIG. 2, in this implementation, in order to further ensure uniform diffusion of ions in the light-emitting layer 12, the first potential barrier sub-layer 1241 and the third potential barrier sub-layer 1243 in the second potential barrier layer 124 are not doped with ions, and the second potential barrier sub-layer 1242 in the second potential barrier layer 124 is doped with ions and has a same doping type as the second-type semiconductor layer 13, for example, P-type doped. In this implementation, the second potential barrier sub-layer 1242 in the second potential barrier layer 124 is doped with zinc ions, such as diethylzinc (DEZn), and a doping concentration of the zinc ions is in a range of 6 ×10¹⁷ atoms/cm² to 1 ×10¹⁸ atoms/cm², such as 7 × 10¹⁷ atoms/cm², 8 × 10¹⁷ atoms/cm², or 9 ×10¹⁷ atoms/cm². In other implementations, zinc ions can be doped in the first potential barrier sub-layer and/or the third potential barrier sub-layer, and the first potential barrier sub-layer and/or the third potential barrier sub-layer each have a same dopant source and a same doping concentration as the second potential barrier sub-layer. The first potential barrier sub-layer or the third potential barrier sub-layer may be doped alone, and all or part of the first potential barrier sub-layer, the second potential barrier sub-layer, and the third potential barrier sub-layer may be doped.

Referring to FIG. 2, part of potential barrier layers in the intermediate region of the light-emitting layer 12 is P-type doped with diethylzinc. A quantum well structure modulated by such doping can provide a higher hole concentration and reduce a series resistance, so that the device has a better thermal effect than a conventional structure, and moreover, lower junction heat can make carriers in a quantum well easier to be trapped, thereby increasing a luminous efficiency. In addition, higher hole concentration can improve a recombination efficiency, thereby improving a light output efficiency.

Referring to FIG. 2, in an implementation of the disclosure, the first potential well layers 121 and the first potential barrier layers 122 that are stacked repeatedly are formed as follows. First, for example, at a temperature of 690° C. to 710° C. and a chamber pressure of 45 mbar to 55 mbar, a group V source of phosphine (PH₃) is inlet, a certain proportion of a group III source of trimethylgallium or trimethylindium is inlet with hydrogen as a carrier gas, a deposition time is controlled, and the first potential well layer 121 (Ga_{X11}In_{1-X11}P) with a preset thickness (e.g., 9 nm) is grown. A proportion of the group V source/the group III source is, for example, 100-150. Second, after the first potential well layer 121 is formed, a reaction chamber is opened to feed/inlet trimethylaluminum, a proportion of the group III source of trimethylgallium, a proportion of a group III source of trimethylaluminum, and a proportion of the group III source of trimethylindium are adjusted, and the first potential barrier sub-layer 1221 with a preset thickness (e.g., 7 nm), the second potential barrier sub-layer 1222 with a preset thickness (e.g., 7 nm), and the third potential barrier sub-layer 1223 with a preset thickness (e.g., 7 nm) are sequentially deposited to form the first potential barrier layer 122 (A1_{X12}Ga_{1-X12})_{0.5}In_{0.5}P with a preset thickness (e.g., 21 nm). The operations of forming the first potential well layer 121 and the first potential barrier layer 122 are repeated, to grow four to six repetitions of the first potential well layer 121 and the first potential barrier layer 122.

Referring to FIG. 2, in an implementation of the disclosure, after four to six repetitions of the first potential well layer 121 and the first potential barrier layer 122 are formed, the second potential well layers 123 and the second potential barrier layers 124 are formed on the first potential well layers 121 and the first potential barrier layers 122 that are repeatedly stacked. First, for example, at a temperature of 690° C. to 710° C. and a chamber pressure of 45 mbar to 55 mbar, a group V source of phosphine (PH₃) is inlet, a certain proportion of a group III source of trimethylgallium or trimethylindium is inlet with hydrogen as a carrier gas, a deposition time is controlled, and the second potential well layer 123 (Gaₓ₁₁In₁₋ₓ₁₁P) with a preset thickness (e.g., 9 nm) is grown. A proportion of the group V source/the group III source is, for example, 100-150. Second, after the second potential well layer 123 is formed, the second potential barrier layer 124 is formed on the second potential well layer 123. Specifically, a reaction chamber is opened to inlet trimethylaluminum, a proportion of the group III source of trimethylgallium, a group III source of trimethylaluminum, and a proportion of the group III source of trimethylindium are adjusted, and the first potential barrier sub-layer 1241 with a preset thickness (e.g., 7 nm) is deposited. After the first potential barrier sub-layer 1241 is formed, a process condition for forming the first potential barrier sub-layer 1241 is kept unchanged, a certain effective amount of diethylzinc (i.e., a dopant source) is inlet, a deposition time is controlled, and the second potential barrier sub-layer 1242 with a preset thickness (e.g., 7 nm) is grown, where a doping concentration of zinc ions in the second potential barrier sub-layer 1242 is kept in a range of 6 ×10¹⁷ atoms/cm² to 1 ×10¹⁸ atoms/cm². After the second potential barrier sub-layer 1242 is formed, stop inletting of the diethylzinc (i.e., a dopant source), other growth conditions are kept unchanged, a deposition time is controlled, and the third potential barrier sub-layer 1243 with a preset thickness (e.g., 7 nm) is grown, so that the second potential barrier layer 124 with dopant ions in the middle is formed. The operations of forming the second potential well layer 123 and the second potential barrier layer 124 are repeated, to grow four to six repetitions of the second potential well layer 123 and the second potential barrier layer 124.

Referring to FIG. 2, in an implementation of the disclosure, after four to six repetitions of the second potential well layer 123 and the second potential barrier layer 124 are formed, four to six repetitions of the third potential well layer 125 and the third potential barrier layer 126 are formed on the second potential well layers 123 and the second potential barrier layers 124 that are repeatedly stacked. A method for forming the third potential well layer 125 is the same as a method for forming the first potential well layer 121. A method for forming the first potential barrier sub-layer 1261, the second potential barrier sub-layer 1262, and the third potential barrier sub-layer 1263 in the third potential barrier layer 126 is the same as a method for forming the first potential barrier sub-layer 1221, the second potential barrier sub-layer 1222, and the third potential barrier sub-layer 1223 in the first potential barrier layer 122, which will not be repeated herein.

Referring to FIG. 1 and FIG. 4, in an implementation of the disclosure, the second-type semiconductor layer 13 is formed on the light-emitting layer 12, and the second-type semiconductor layer 13 may be a P-type semiconductor layer in which majority carriers are holes or an N-type semiconductor layer in which majority carriers are electrons. In this implementation, the second-type semiconductor layer 13 is, for example, a P-type semiconductor layer, and the second-type semiconductor layer is doped with acceptor impurities, such as magnesium (Mg) or zinc (Zn). The second-type semiconductor layer 13 includes a second waveguide layer 131, a second confinement layer 132, a transition layer 133, and a window layer 134 which are disposed on the light-emitting layer 12 in sequence.

Specifically, referring to FIG. 1, FIG. 3, and FIG. 4, in an implementation of the disclosure, the first waveguide layer 116 is in direct contact with one side of the light-emitting layer 12, and a second waveguide layer 131 corresponding to the first waveguide layer 116 is in direct contact with another side of the light-emitting layer 12. The second waveguide layer 131 is disposed on the light-emitting layer 12, and the second waveguide layer 131 is, for example, made of P-type aluminum gallium indium phosphide (Alₓ₅Ga₁₋ₓ₅InP), where X5 is, for example, in a range of 0.5 to 0.7, such as 0.55, 0.6, or 0.65. In this implementation, a thickness of the second waveguide layer 131 is, for example, in a range of 30 nm to 60 nm, such as 30 nm, 40 nm, 50 nm, or 60 nm. The second waveguide layer 131 of the disclosure is not doped with other ions, which can prevent impurities in other second-type semiconductor layers 13 from diffusing into the light-emitting layer. The second confinement layer 132 is disposed on the second waveguide layer 131, and the second confinement layer 132 is, for example, made of P-type aluminum indium phosphide (Alₓ₆In₁₋ₓ₆P), where X6 is, for example, 0.5, that is, the second confinement layer 132 is made of Al_{0.5}In_{0.5}P. In this implementation, a thickness of the second confinement layer 132 is, for example, in a range of 30 nm to 80 nm, such as 50 nm, 60 nm, or 70 nm. As an example, the second confinement layer 132 is doped with magnesium ions, and has an ion doping concentration of 7 ×10¹⁷ atoms/cm² to 1 ×10¹⁸ atoms/cm², which can provide holes for the light-emitting layer and prevent carriers from overflowing the light-emitting layer.

Referring to FIG. 1 and FIG. 4, in an implementation of the disclosure, the transition layer 133 is disposed on the second confinement layer 132, and the transition layer 133 is, for example, made of P-type aluminum gallium indium phosphide ((Alₓ₇Ga₁₋ₓ₇)_{0.5}In_{0.5}P), where X7 is, for example, in a range of 0.2 to 0.4, such as 0.25, 0.3, or 0.35. In this implementation, a thickness of the transition layer 133 is, for example, in a range of 30 nm to 40 nm, such as 32 nm, 35 nm, or 37 nm. As an example, the transition layer 133 is doped with magnesium ions, and has an ion doping concentration of 2 ×10¹⁸ atoms/cm² to 3 ×10¹⁸ atoms/cm². The transition layer 133 has a relatively high doping concentration, which is beneficial to growing a crystal on gallium phosphide. The window layer 134 is disposed on the transition layer 133 and used as the current spreading layer 114 and a light output layer. The window layer 134 can form a good ohmic contact with an electrode. The window layer 134 is, for example, made of P-type gallium phosphide (GaP). A thickness of the window layer 134 is, for example, in a range of 40 nm to 90 nm, such as 50 nm, 60 nm, or 70 nm. For example, the window layer 134 is doped with magnesium ions, and has an ion doping concentration of 1 ×10¹⁸ atoms/cm² to 2 ×10¹⁸ atoms/cm².

Referring to FIG. 1 and FIG. 4, in an implementation of the disclosure, the second waveguide layer 131, the second confinement layer 132, the transition layer 133, and the window layer 134 are sequentially deposited on the light-emitting layer 12 through MOCVD. After the second-type semiconductor layer 13 is formed, a semiconductor epitaxial structure is formed. After a complete semiconductor epitaxial structure is formed, epitaxial inspection is performed on the semiconductor epitaxial structure, and a qualified semiconductor epitaxial structure can be used to prepare an LED.

Referring to FIG. 3, FIG. 4, and FIG. 5, in an implementation of the disclosure, the LED is, for example, a micro LED. A recess is formed by etching one side of the semiconductor epitaxial structure, and in the recess, the ohmic contact layer 113 in the first-type semiconductor layer 11 is exposed. By evaporation and/or sputtering techniques, the first electrode 14 is deposited on the ohmic contact layer 113 in the recess, and the second electrode 15 is deposited on the window layer 134. The first electrode 14 and the second electrode 15 are electrodes of equal height. In this implementation, the first electrode 14 is an N-type electrode, and the first electrode 14 is, for example, made of germanium and/or copper; the second electrode 15 is a P-type electrode, and the second electrode 15 is, for example, made of beryllium and/or copper. In some implementations, a passivation layer 16 is further deposited on the second-type semiconductor layer 13 as a protective layer or package for the LED. For example, the passivation layer 16 is made of silicon oxide, silicon nitride or phosphosilicate glass, etc.

In summary, according to the semiconductor epitaxial structure and the method for manufacturing the same, and the LED of the disclosure, the light-emitting layer is formed on the first-type semiconductor layer, and the second-type semiconductor layer is formed on the light-emitting layer, to form the semiconductor epitaxial structure. The first electrode is deposited on the first-type semiconductor layer, and the second electrode is deposited on the second-type semiconductor layer, to form the LED. The semiconductor epitaxial structure and the LED of the disclosure have a relatively good thermal effect and can improve a light output efficiency.

It should be understood that, the application of the disclosure is not limited to the foregoing exemplary implementations. Those of ordinary skill in the art can made improvements or equivalent substitutions to the disclosure according to the above descriptions, and all these improvements and equivalent substitutions, however, shall all be encompassed within the protection scope of the appended claims of the disclosure.

What is claimed is:

1. A semiconductor epitaxial structure, comprising:
a first-type semiconductor layer;
a light-emitting layer disposed on the first-type semiconductor layer; and
a second-type semiconductor layer disposed on the light-emitting layer, wherein
the light-emitting layer comprises potential well layers and potential barrier layers that are repeatedly stacked, at least part of potential barrier layers belonging to intermediate layers of the light-emitting layer is doped, and has a doping type same as the second-type semiconductor layer.

2. The semiconductor epitaxial structure of claim 1, wherein a total number of repetitions of the potential well layer and the potential barrier layer ranges from 12 to 20.

3. The semiconductor epitaxial structure of claim 1, wherein a number of repetitions of a potential barrier layer doped and a corresponding potential well layer ranges from 4 to 6.

4. The semiconductor epitaxial structure of claim 1, wherein the potential barrier layer comprises a first potential barrier sub-layer, a second potential barrier sub-layer, and a third potential barrier sub-layer, and the first potential barrier sub-layer, the second potential barrier sub-layer, and the third potential barrier sub-layer are sequentially stacked.

5. The semiconductor epitaxial structure of claim 4, wherein
the first potential barrier sub-layer in the potential barrier layer doped is doped; and/or
the second potential barrier sub-layer in the potential barrier layer doped is doped; and/or
the third potential barrier sub-layer in the potential barrier layer doped is doped.

6. The semiconductor epitaxial structure of claim 1, wherein the potential barrier layer doped is P-type doped, and a dopant source of the potential barrier layer doped is diethylzinc.

7. The semiconductor epitaxial structure of claim 1, wherein the first-type semiconductor layer comprises:
an etching stop layer; and
an ohmic contact layer formed on the etching stop layer.

8. The semiconductor epitaxial structure of claim 7, wherein the first-type semiconductor layer further comprises:
a current spreading layer formed on the ohmic contact layer;
a first confinement layer formed on the current spreading layer; and
a first waveguide layer formed on the first confinement layer.

9. The semiconductor epitaxial structure of claim 1, wherein the second-type semiconductor layer comprises:
a second waveguide layer disposed on the light-emitting layer;
a second confinement layer disposed on the second waveguide layer;
a transition layer disposed on the second confinement layer; and
a window layer disposed on the transition layer.

10. A method for manufacturing a semiconductor epitaxial structure, comprising:
providing a substrate;
forming a first-type semiconductor layer on the substrate;
forming a light-emitting layer on the first-type semiconductor layer; and
forming a second-type semiconductor layer on the light-emitting layer, wherein
the light-emitting layer comprises potential well layers and potential barrier layers that are repeatedly stacked, at least part of potential barrier layers belonging to intermediate layers of the light-emitting layer is doped, and has a doping type same as the second-type semiconductor layer.

11. The method of claim 10, wherein forming the potential well layer comprises:
inletting phosphine, and inletting a preset proportion of trimethylgallium or a preset proportion of trimethylindium with hydrogen as a carrier gas, under a preset temperature and chamber pressure; and
controlling a first deposition time and growing the potential well layer with a first thickness.

12. The method of claim 11, wherein the potential barrier layer comprises a first potential barrier sub-layer, a second potential barrier sub-layer, and a third potential barrier sub-layer, and forming a potential barrier layer doped comprises:
inletting trimethylaluminum into a reaction chamber, adjusting a proportion of the trimethylgallium, a proportion of the trimethylaluminum, and a proportion of the trimethylindium, controlling a second deposition time, and growing a first potential barrier sub-layer with a second thickness, after forming the potential well layers;
maintaining a growing condition for forming the first potential barrier sub-layer, inletting diethylzinc into the reaction chamber, controlling the second deposition time, and growing a second potential barrier sub-layer with a third thickness; and
maintaining a growing condition for forming the second potential barrier sub-layer, stopping inletting of the diethylzinc into the reaction chamber, controlling the second deposition time, and growing a third potential barrier sub-layer with a fourth thickness.

13. The method of claim 12, wherein a doping concentration of zinc ions in the second potential barrier sub-layer ranges from 6×10¹⁷ atoms/cm² to 1×10¹⁸ atoms/cm².

14. A light-emitting diode (LED), comprising:
a semiconductor epitaxial structure, wherein the semiconductor epitaxial structure comprises:
a first-type semiconductor layer;
a light-emitting layer disposed on the first-type semiconductor layer; and
a second-type semiconductor layer disposed on the light-emitting layer, wherein
the light-emitting layer comprises potential well layers and potential barrier layers that are repeatedly stacked, at least part of potential barrier layers belonging to intermediate layers of the light-emitting layer is doped, and has a doping type same as the second-type semiconductor layer;
a first electrode coupled with the first-type semiconductor layer; and
a second electrode coupled with the second-type semiconductor layer.

15. The LED of claim 14, wherein a total number of repetitions of the potential well layer and the potential barrier layer ranges from 12 to 20.

16. The LED of claim 14, wherein a number of repetitions of a potential barrier layer doped and a corresponding potential well layer ranges from 4 to 6.

17. The LED of claim 14, wherein the potential barrier layer comprises a first potential barrier sub-layer, a second potential barrier sub-layer, and a third potential barrier sub-layer, and the first potential barrier sub-layer, the second potential barrier sub-layer, and the third potential barrier sub-layer are sequentially stacked.

18. The LED of claim 14, wherein the potential barrier layer doped is P-type doped, and a dopant source of the potential barrier layer doped is diethylzinc.

19. The LED of claim 14, wherein the first-type semiconductor layer comprises:
an etching stop layer;
an ohmic contact layer formed on the etching stop layer;
a current spreading layer formed on the ohmic contact layer;
a first confinement layer formed on the current spreading layer; and
a first waveguide layer formed on the first confinement layer.

20. The LED of claim 14, wherein the second-type semiconductor layer comprises:
a second waveguide layer disposed on the light-emitting layer;
a second confinement layer disposed on the second waveguide layer;
a transition layer disposed on the second confinement layer; and
a window layer disposed on the transition layer.
